(19) United States
(12) Patent Application Publication
(10) Pub. No.: US 2011/0220023 A1
(43) Pub. Date: Sep. 15, 2011

(54) NITROGEN GAS INJECTION APPARATUS

(76) Inventor: Seung Yong Lee, Gyeonggi-do (KR)

(21) Appl. No.: 13/129,728

(22) PCT Filed: Aug. 3, 2010
(86) PCT No.: PCT/KR2010/005097

§ 371 Date: May 17, 2011

(30) Foreign Application Priority Data
Aug. 10, 2009 (KR) 10-2009-0073497

(51) Int. Cl. C23C 16/00

(52) U.S. Cl. 118/715

(57) ABSTRACT

The present invention relates to a nitrogen gas injection apparatus for semiconductor fabrication equipment or LCD fabrication equipment, which can be simply manufactured and which thus reduces manufacturing costs, and which enables a nitrogen gas injection direction to correspond to the flow direction of reaction by-products, to thereby inject nitrogen gas in an effective manner without disturbing the flow of reaction by-products. The nitrogen gas injection apparatus comprises: a pair of flanged pipes having flanges; a ring-shaped injection nozzle coupled along the inner wall of one of the flanged pipes coupled together, to supply nitrogen gas into the flanged pipes; and a nitrogen supply line connected to the injection nozzle to supply nitrogen gas. The interior of the injection nozzle has a hole to enable the nitrogen gas supplied in a circumferential direction to flow, and a plurality of injection holes communicating with the hole to inject the supplied nitrogen gas into the flanged pipes. The injection holes are formed at the position protruding from the inner surface of one of the flanged pipes to inject nitrogen gas in the flow direction of reaction by-products.

### TECHNICAL FIELD

The present invention relates to semiconductor device and LCD manufacturing apparatuses, and more particularly, to a nitrogen gas injection device which can be easily fabricated with a low production cost and controls a nitrogen gas injection direction to coincide with a byproduct flow direction so that a nitrogen gas can be effectively injected without disturbing the flow of byproduct gas.

### BACKGROUND ART

Generally, a semiconductor manufacturing process includes a fabrication process and a assembly & test process. The fabrication process means a process for manufacturing semiconductor chips by depositing thin films on a wafer in various process chambers and selectively etching the deposited films in a repeated way to form a predetermined pattern. The assembly & test process means a process of individually separating the chips manufactured in the fabrication process and then coupling the individual chip to a lead frame to assemble a final product.

At this time, the process of depositing thin films on a wafer or etching the films deposited on the wafer is performed at high temperature by using harmful gases such as silane, arsine, and boron chloride and process gases such as hydrogen in a process chamber. While such a process is performed, a large amount of various pyrophoric gases and byproduct gas containing harmful components and corrosive impurities are generated in the process chamber.

Thus, a semiconductor manufacturing apparatus is provided with a scrubber, which purifies byproduct gas discharged from a process chamber and discharges the purified byproduct gas to the atmosphere, at a downstream side of a vacuum pump for making the process chamber into a vacuous state.

However, while flowing along an outlet-side vacuum pipe of the process chamber, an outlet-side exhaust pipe of a vacuum pump, an outlet-side exhaust pipe of a scrubber, a main duct, and the like in order, the harmful byproduct gas generated from the process chamber is easily solidified and accumulated, thereby resulting in clogging.

Thus, in order to prevent the clogging caused by the solidified byproduct gas, a jacket heater is commonly used which is entirely surrounding a certain region of an exhaust pipe to keep the inside of the exhaust pipe to be worm. However, there is a problem in that the jacket heater is not so efficient in powder accumulation in spite of high installation costs since many portions of the pipe should be surrounded by the heater.

Meanwhile, in order to improve such a jacket heater, Korean Laid-open Patent Publication No. 2005-88649 discloses a nitrogen supply device which injects a high-temperature nitrogen gas into a pipe in which a byproduct gas flows. FIG. 1 is a view illustrating the conventional nitrogen supply device.

As shown in FIG. 1, the conventional nitrogen supply device includes a flange pipe 2 connected to pipes where a byproduct gas flows and injecting a high-temperature nitrogen gas therein, an outer pipe 23 surrounding an outer peripheral surface of the flange pipe 2 and defining a double-wall structure for the supply of a nitrogen gas, a heater 1 for heating the nitrogen gas supplied to the flange pipe 2 through a nitrogen supply line 14, and the like.

In this configuration, the flange pipe 2 is connected to a middle of a pipe where a byproduct gas flows. Thereafter, if a nitrogen gas heated by the heater 1 operating with the power received from a power supply 3 is supplied to a space between the flange pipe 2 and the outer pipe 23, the supplied high-temperature nitrogen gas is injected through a plurality of injection holes 22 formed in a body 21 of the flange pipe 2 and is mixed with a byproduct gas flowing via the flange pipe 2. Thus, the byproduct gas is prevented from being solidified and accumulated due to a decreased temperature.

However, in the conventional nitrogen supply device, the outer pipe 23 should be installed to the outer side of the flange pipe 2 by means of welding or the like to make a double-wall structure, and several injection holes 22 should be formed at locations corresponding to the flange pipes 2 in order to inject and supply a nitrogen gas. For this reason, a process of manufacturing the conventional nitrogen supply device becomes complicated, and a production cost is increased. In addition, it is not easy to form a plurality of fine injection holes 22 in the thick body 21 of the flange pipe 2, and thus it is difficult to inject a nitrogen gas uniformly.

In addition, the conventional nitrogen supply device cannot easily control the injection of a nitrogen gas minutely, and thus, it is not difficult to install the device to an outlet-side vacuum pipe of a process chamber. In this case, if an electronic flow rate control device is used for controlling the amount of a nitrogen gas supplied, the product price is inevitably increased.

Further, there is a problem in that the flow of byproduct gas is disturbed due to the injection of the nitrogen gas. For this reason, it is difficult to install the conventional nitrogen supply device to an outlet-side vacuum pipe of a process chamber, which is sensitive to a pressure change. Also, it may be difficult to uniformly inject a nitrogen gas since the injection holes are clogged by the byproduct gas.

### DISCLOSURE

### Technical Problem

The present invention is conceived to solve the aforementioned problems in the prior art. An object of the present invention is to provide a nitrogen gas injection device which controls a nitrogen gas injection direction to coincide with a byproduct flow direction so that an injecting ability is improved without disturbing the flow of byproduct gas.

### Technical Solution

According to an aspect of the present invention for achieving the objects, there is provided a nitrogen gas injection device, which includes a pair of flange pipes, each flange pipe having a flange for connecting to a pipe allowing byproduct gas to be carried therethrough; an injection nozzle coupled in a ring shape between the pair of flange pipes along walls of the flange pipes to supply nitrogen gas into the flange pipes; and a nitrogen supply line connected to the injection nozzle to supply nitrogen gas, wherein the injection nozzle has a hollow defined therein along a circumferential direction to allow the nitrogen gas to move, the injection nozzle includes a plurality of injection holes communicating with the hollow to allow the supplied nitrogen to be injected into the flange pipes, and the injection holes are formed at locations protruding from an inner peripheral surface of the flange pipes to inject nitrogen gas in the same direction as a byproduct gas flow direction.

Here, the injection nozzle may include a coupling portion formed on an outer side thereof along a circumferential direction and coupled to the wall of the flange pipe; and a protrusion formed on an inner side of the coupling portion along a circumferential direction to protrude from an inner peripheral surface of the flange pipe, the injection holes being formed in the protrusion in the same direction as a byproduct gas outflow direction. This configuration may provide an ejector effect and accelerate the flow of byproduct.

Also, the injection nozzle may be configured by coupling a first divided portion and a second divided portion, into which the injection nozzle is divided along a circumferential direction, the first and second divided portions being respectively located in byproduct gas inflow and outflow directions, the first divided portion may be provided with a first flow hole defining a part or the entirety of the hollow along a circumferential direction, and the injection hole may be formed in the second divided portion to correspondingly communicate with the first flow hole.

In addition, an opposite inner peripheral surface of the protrusion where no injection hole is formed may have an inner diameter gradually increasing to reduce resistance against the byproduct gas, thereby decreasing a difference in thickness between the opposite inner peripheral surface of the protrusion and an inner peripheral surface of the flange pipe.

Also, the nitrogen gas injection device may further include a heater installed in a middle of the nitrogen supply line to heat the nitrogen gas supplied to the injection nozzle.

In addition, the nitrogen gas injection device may further include an orifice pipe installed in a middle of the nitrogen supply line to control the supply amount of nitrogen gas.

### Advantageous Effects

The nitrogen gas injection device according to the present invention does not disturb the flow of byproduct gas but rather improves it since nitrogen gas is injected toward an outlet-side in a direction to coincide with a byproduct gas flow direction.

Also, in the present invention, since nitrogen gas is injected in the same direction as byproduct gas flows, the nitrogen gas can be smoothly injected due to the flow of the byproduct gas.

In addition, according to the present invention, it is not apprehended that the injection holes through which nitrogen gas is injected clogged by the byproduct gas.

Also, in the present invention, a curved portion for preventing abrupt contact between the byproduct gas and an injection nozzle body allows the flow of byproduct gas not to be disturbed by the protrusion of the injection nozzle.

Further, in the present invention, the injection nozzle is configured to be divided into two parts along a circumferential direction and then coupled, which makes its production easy. Also, a ring-shaped injection nozzle may be simply installed to the flange pipe, whereby the injection nozzle can be easily produced and installed with a low cost without any complicated or difficult process of constructing a double-wall to the flange pipe.

Also, in a case where the nitrogen gas injection device of the present invention is installed to a vacuum pipe, the injection of nitrogen gas may be minutely controlled using a simple and inexpensive orifice pipe, instead of using an expensive part such as an electronic flow rate valve. Thus, the nitrogen gas injection device of the present invention may be installed regardless of an outlet-side vacuum pipe of a process chamber.

In addition, an inner diameter of the inner peripheral surface of the protrusion is gradually increased toward an inflow side of the byproduct gas to enhance the effect of an ejector while reduce the resistance against the byproduct gas, which may further accelerate the flow of byproduct gas.

Also, according to the present invention, since a flange pipe available from the market may be used as it is, there is no need for additional equipment or cost for producing the flange pipe.

### DESCRIPTION OF DRAWINGS

FIG. 1 is a view illustrating a conventional nitrogen supply device;

FIG. 2 is a view showing an installed state of a nitrogen gas injection device according to the present invention;

FIG. 3 is an exploded perspective view illustrating the configuration of the nitrogen gas injection device according to the present invention;

FIG. 4 is a perspective view illustrating an injection nozzle according to the present invention;

FIG. 5 is a sectional view taken along line I-I of FIG. 4;

FIG. 6 is a sectional view illustrating the operation of gas flow according to the present invention; and

FIG. 7 is a view illustrating a byproduct processing mechanism for manufacture of a semiconductor according to the present invention.

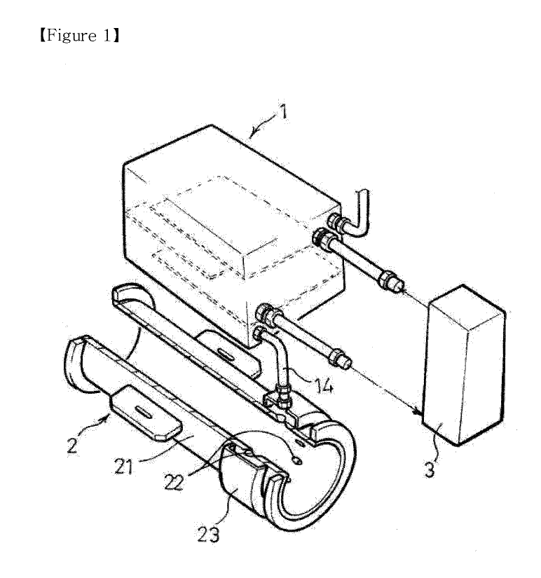

### BEST MODE

Hereinafter, preferred embodiments according to the aforementioned technical spirit of the present invention will be described in detail with reference to the accompanying drawings.

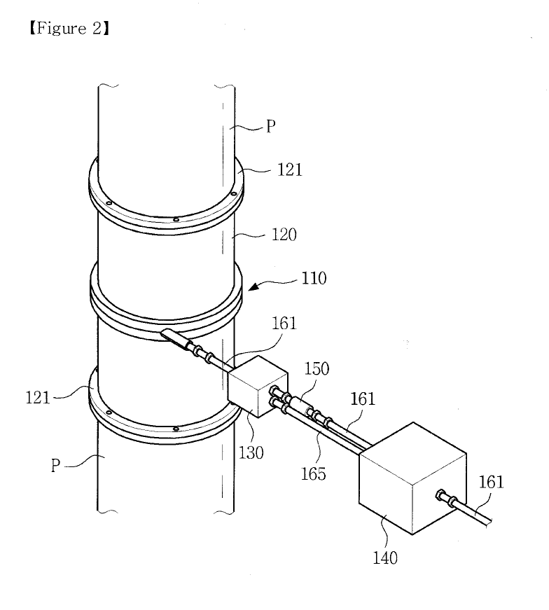

FIG. 2 is a view showing an installed state of a nitrogen gas injection device according to the present invention.

As shown in the figure, the nitrogen gas injection device of the present invention may be selectively installed to any pipe P at an outlet-side of a process chamber, an inlet- or outlet-side of a vacuum pump, or an inlet- or outlet-side of a scrubber. The nitrogen gas injection device of the present invention may be easily installed to each pipe P, and control nitrogen gas to be injected in the same direction as a byproduct gas flow direction to thereby be easily installed to an exhaust pipe of a vacuum pump and an exhaust pipe of a scrubber as well as a vacuum pipe serving as an outlet-side pipe of a process chamber which should not give an influence on the degree of vacuum during a process.

As mentioned above, in the present invention, nitrogen gas is injected in the same direction as a byproduct gas flow direction not to disturb the flow of the byproduct gas, and also the nitrogen gas injection device is configured to be easily fabricated and installed.

Hereinafter, the configuration of the present invention will be described in detail.

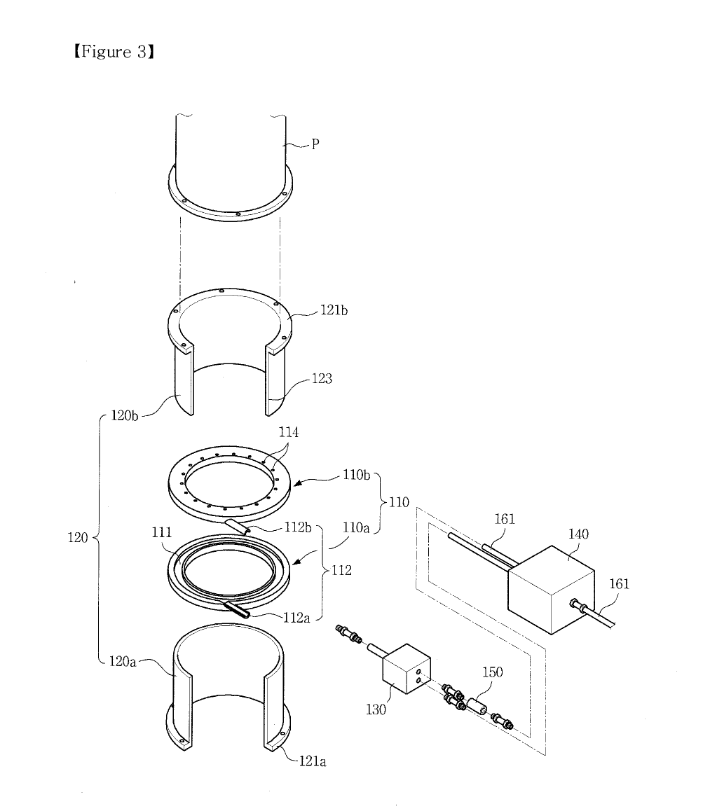

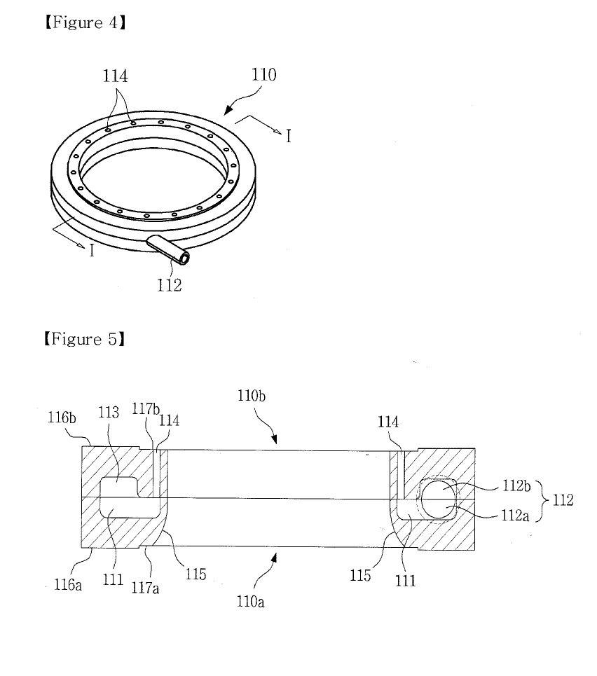

FIG. 3 is an exploded perspective view illustrating the configuration of the nitrogen gas injection device according to the present invention; FIG. 4 is a perspective view illustrating an injection nozzle according to the present invention; and FIG. 5 is a sectional view taken along line I-I of FIG. 4.

As shown in the figures, the nitrogen gas injection device of the present invention includes a ring-shaped injection nozzle 110, a flange pipe 120, a heater 130, an orifice pipe 150, and a control box 140.

The injection nozzle 110 is coupled in a ring shape between a pair of flange pipes 120 along walls of the flange pipes 120 and is installed to supply nitrogen into the flange pipes 120. To this end, the injection nozzle 110 has a hollow 111 and 113 defined therein for receiving nitrogen gas therein and allowing the gas to circulate, and a plurality of injection holes 114 communicating with the hollow 111 and 113 is formed in the injection nozzle 110 to inject nitrogen gas. In particular, the injection holes 114 are formed at protruding locations from the inner peripheral surface of the flange pipe 120 so that the nitrogen gas is injected in the same direction as the byproduct gas flow direction. Now, the configuration of the injection nozzle 110 will be described below in more detail.

The injection nozzle 110 includes in brief coupling portions 116a and 116b and protrusions 117a and 117b. The coupling portions 116a and 116b are formed on an outer side along a circumferential direction and coupled with the wall of the flange pipe 120. The protrusions 117a and 117b are formed on the inner side of the coupling portions 116a and 116b along a circumferential direction and protrude from the inner peripheral surface of the flange pipe. The plurality of injection holes 114 are formed in the protrusions 117a and 117b in a direction along which byproduct gas flows out. If the injection holes 114 are formed in a direction along which byproduct gas flows out as mentioned above, the interference with the byproduct gas flowing in the flange pipe 120 disappears so that the injected nitrogen gas does not substantially disturb the byproduct gas flow. In addition, the byproduct gas does not substantially disturb the injection of the nitrogen gas or clog the injection holes 114.

Meanwhile, the injection nozzle 110 is configured by coupling a first divided portion 110a and a second divided portion 110b, into which the injection nozzle 110 is divided along a circumferential direction, for the convenience of fabrication. The first divided portion 110a is located in a byproduct gas inflow direction, and the second divided portion 110b is located in a byproduct gas outflow direction. Here, the first divided portion 110a is provided with the first flow hole 111 defining a part (or, the entirety) of the hollow 111 and 113 along a circumferential direction, and the second divided portion 110b is provided with the second flow hole 113 defining the hollow 111 and 113 together with the first flow hole 111. Also, the injection holes 114 are formed in the second divided portion 110b to communicate with the first flow hole 111. However, the hollow 111 and 113 can be formed even though the second flow hole 113 is not formed in the second divided portion 110b.

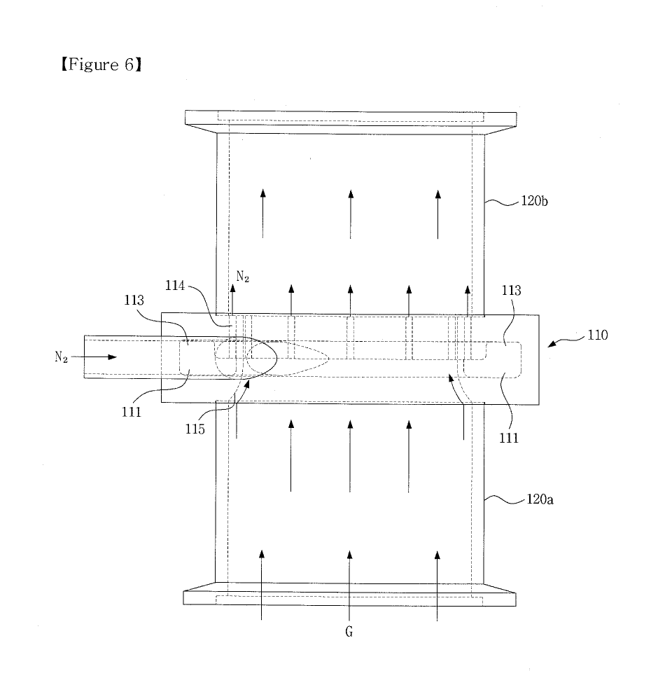

In addition, a curved portion 115 with an inner diameter increasing toward a byproduct inflow side is provided in the inner peripheral surface of the protrusion 117a of the second divided portion 113 in order to reduce the resistance against the byproduct gas, as the cross-section shown in FIG. 6. The curved portion 115 allows the byproduct gas flowing in the flange pipe 120 not to be disturbed by the protrusions 117a and 117b of the injection nozzle 110 and increases a flow rate of the byproduct gas due to an ejector effect. Thus, the flow of byproduct gas is smooth primarily due to the injection of nitrogen gas, and the flow of byproduct gas is smoother secondarily by means of the curved portion 115. Also, the increased flow rate of the byproduct gas as mentioned above interactively allows the injection of nitrogen gas to be smooth and improves the injecting capability of nitrogen gas.

The flange pipe 120 servers to allow easy connection with each pipe and includes a hollow cylinder-shaped body and flanges 121 provided respectively at both ends of the body for the connection with each pipe. A standardized product, as the flange pipe 120, available from the market may be used as it is. However, the flange pipe is divided into a first flange pipe 120 and a second flange pipe 120 so that the injection nozzle 110 may be installed therebetween.

The heater 130 servers to heat nitrogen gas supplied to the injection nozzle 110. To this end, various methods known in the art may be used. For example, if nitrogen gas passes through a pipe having a heater therein, the heater may heat the nitrogen gas. However, it is just depicted in the figures that a nitrogen supply line 161 and a power line 165 for supplying power are connected to the heater 130.

In a case where the present invention is installed to a vacuum pipe, the orifice pipe 150 is installed in the middle of the nitrogen supply line 161 and serves to control the supply amount of nitrogen gas introduced into the heater 130. In a case where the vacuum pipe is an outlet-side pipe of a process chamber, the orifice pipe 150 should not give an influence on the degree of vacuum during the process and should not give an overload to a dry pump. Thus, the orifice pipe 150 is sized so that it allows a relatively small amount of nitrogen gas to pass therethrough. Since the supply amount of nitrogen gas may be controlled by means of the orifice pipe 150 which is inexpensive and capable of controlling the injection minutely, there is an advantage in that an expensive machine such as an electronic flow rate controller is not inevitably installed to control the supply amount of nitrogen gas.

The control box 140 controls the heater 130 to adjust the degree of heating of nitrogen gas. To this end, the control box 140 includes a controller (not shown) for controlling the heater 130 how much to heat the nitrogen gas. Further, a flow meter for controlling the supply amount of nitrogen gas in the nitrogen supply line 161 is installed to the control box 140 to control a basic amount of supplied nitrogen gas. Also, an electronic flow rate control value (not shown) may be additionally installed.

Hereinafter, a byproduct processing mechanism for manufacture of a semiconductor and LCD using the nitrogen gas injection device according to the present invention will be described.

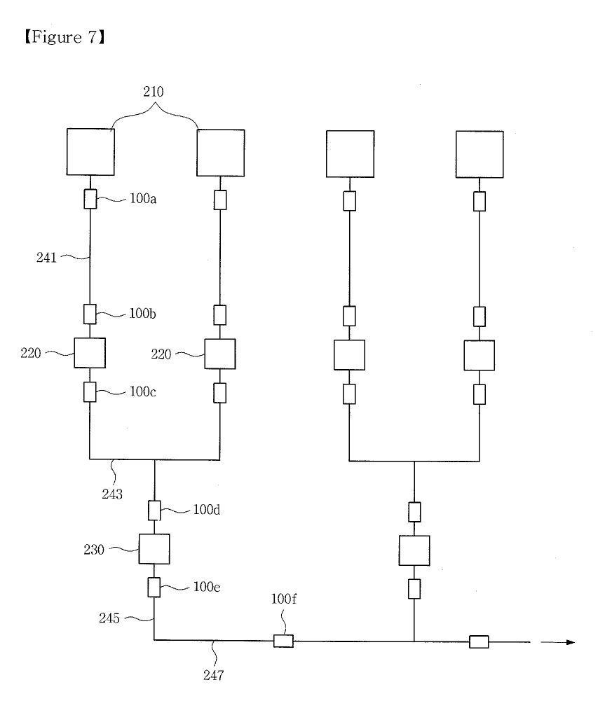

FIG. 7 is a view illustrating a byproduct processing mechanism for manufacture of a semiconductor according to the present invention.

As shown in the figure, the nitrogen gas injection device of the present invention may be installed to any pipe 241, 243 or 245 at an outlet-side of a process chamber 210 for manufacturing a semiconductor or LCD, an inlet- or outlet-side of a vacuum pump 220, or an inlet- or outlet-side of a scrubber 230. The nitrogen gas injection device may also be installed to a main duct 247 at which the pipe 245 is joined at the outlet-side of the scrubber 230. Since the nitrogen gas injection device may be easily installed to each pipe by means of the flange pipe 120, no influence is given to the outflow pipe 243 of the vacuum pump, the outflow pipe 245 of the scrubber, and the main duct 247, which need a relatively great amount of nitrogen gas, as well as to the degree of vacuum during the process. In addition, the nitrogen gas injection device may be simply installed to the vacuum pipe 241 that is a pipe at an outlet-side of the process chamber to which a relatively small amount of nitrogen gas should be supplied carefully in order not to give an overload to a dry pump.

Here, the nitrogen gas injection devices installed to the vacuum pipe 241 at the outlet-side of the process chamber 210 and the inlet-side of the vacuum pump 220 are designated by reference numerals 100a and 100b, respectively. Also, the nitrogen gas injection devices installed to the outflow pipe 243 of the vacuum pump 220 at the outlet-side of the vacuum pump and the inlet-side of the scrubber 230 are designated by reference numerals 100c and 100d, respectively. In addition, the nitrogen gas injection device installed to the pipe at the outlet-side of the scrubber is designated by a reference numeral 100e, and the nitrogen gas injection device installed to the main duct 247 is designated by a reference numeral 100f.

The operation of the nitrogen gas injection device according to the present invention configured as mentioned above will be described below in detail with reference to the accompanying drawings.

The byproduct gas generated from the process chamber 210 flows by a suction force of the vacuum pump 220 to reach the main duct 247 via the vacuum pump 220 and then the scrubber 230. Such flow is then continuously maintained.

At this time, the nitrogen gas injection devices 100a, 100b, 100c, 100d, 100e, and 100f are respectively installed to the vacuum pipe 241 for connecting the process chamber 210 to the vacuum pump 220, the outflow pipe 243 of the vacuum pump 220 for connecting the vacuum pump 220 to the scrubber 230, the outflow pipe 245 of the scrubber 230 for connecting the scrubber 230 to the main duct 247, and the main duct 247 and operate to supply high-temperature nitrogen gas into the respective pipes.

Accordingly, the byproduct gas flowing in each pipe is prevented from being solidified and accumulated at a specific spot due to temperature drop and maintains the smooth flow continuously. The operation of the nitrogen gas injection devices 100a, 100b, 100c, 100d, 100e, and 100f according to the present invention, which are installed to the respective pipes to inject nitrogen gas therein will be described below.

First, nitrogen gas starts to be supplied to each pipe through the nitrogen supply line 161 connected to a nitrogen gas supplying spot (not shown). At this time, a flow rate of the nitrogen gas flowing along the nitrogen supply line 161 is controlled by a flow meter of the control box 140 so that the suitable amount of nitrogen gas necessary to each pipe passes through the pipe. For example, the orifice pipe 150 capable of keeping a small flow of nitrogen gas is installed to the vacuum pipe 241 just after the process chamber 210 in order not to give an influence on the degree of vacuum during the process and give an overload to the dry pump. Meanwhile, the outflow pipe 243 of the vacuum pump 220 connected at the outlet-side of the vacuum pump 220 is insensitive to the flow of byproduct gas and thus allows a more amount of nitrogen gas to flow. Thus, the amount of nitrogen gas is suitably controlled for each pipe by the flow meter of the control box 140.

The nitrogen gas of which the amount is controlled by the flow meter of the control box 140 and the orifice pipe 150 is heated to high temperature while passing through the heater 130. Thereafter, the high-temperature nitrogen gas is supplied into the ring-shaped injection nozzle 110 and is dispersed in the hollow 111 and 113 therein. Then, the nitrogen gas is injected into the flange pipe 120 through the minute injection holes 114.

Meanwhile, the nitrogen gas supplied into the hollow 111 and 113 of the injection nozzle through the nitrogen supply pipe after passing through the orifice pipe 150 circulates along the hollow 111 and 113 and is injected into the flange pipe 120 in a substantially constant amount through the injection holes 114. At this time, the nitrogen gas injected through the injection holes 114 is injected in the same direction as a byproduct gas outflow direction and is thus mixed with the byproduct gas without disturbing the flow of byproduct gas.

In addition, before being mixed with the nitrogen gas, the byproduct gas flows along the curved portion 115 having a gradually expanding shape in the byproduct gas inflow direction, when initially encountering the injection nozzle. Thus, the byproduct gas may maintain smooth flow without any resistance caused by abrupt collision or contact. Also, as the inner diameter becomes decreased due to the curved portion 115, the flow rate of the byproduct is increased, so that the nitrogen gas can be smoothly injected.

As described above, according to the present invention, the nitrogen gas is supplied toward a byproduct gas discharge side in the same direction as a byproduct gas flow direction and thus does not disturb the flow of byproduct gas. Also, the injection holes 114 through which nitrogen gas is injected are not clogged by the byproduct gas.

Although the preferred embodiments of the present invention have been described, the present invention may use various changes, modifications and equivalents. It will be apparent that the present invention may be equivalently applied by appropriately modifying the aforementioned embodiments. Accordingly, the above descriptions do not limit the scope of the present invention defined by the appended claims.

1. A nitrogen gas injection device, comprising:
a pair of flange pipes, each flange pipe having a flange for connecting to a pipe allowing byproduct gas to be carried therethrough;
an injection nozzle coupled in a ring shape between the pair of flange pipes along walls of the flange pipes to supply nitrogen gas into the flange pipes; and
a nitrogen supply line connected to the injection nozzle to supply nitrogen gas,
wherein the injection nozzle has a hollow defined therein along a circumferential direction to allow the nitrogen gas to move, the injection nozzle includes a plurality of injection holes communicating with the hollow to allow the supplied nitrogen to be injected into the flange pipes, and the injection holes are formed at locations protruding from an inner peripheral surface of the flange pipes to inject nitrogen gas in the same direction as a byproduct gas flow direction.

2. The nitrogen gas injection device according to claim 1, wherein the injection nozzle includes a coupling portion formed on an outer side thereof along a circumferential direction and coupled to the wall of the flange pipe; and a protrusion formed on an inner side of the coupling portion along a circumferential direction to protrude from an inner peripheral surface of the flange pipe, the injection holes being formed in the protrusion in the same direction as a byproduct gas outflow direction.

3. The nitrogen gas injection device according to claim 2, wherein the injection nozzle is configured by coupling a first divided portion and a second divided portion, into which the injection nozzle is divided along a circumferential direction, the first and second divided portions being respectively located in byproduct gas inflow and outflow directions, the first divided portion is provided with a first flow hole defining a part or the entirety of the hollow along a circumferential direction, and the injection hole is formed in the second divided portion to correspondingly communicate with the first flow hole.

4. The nitrogen gas injection device according to claim 2, wherein an opposite inner peripheral surface of the protrusion where no injection hole is formed has an inner diameter gradually increasing to reduce resistance against the byproduct gas, thereby decreasing a difference in thickness between the inner peripheral surface of the protrusion and an inner peripheral surface of the flange pipe.

5. The nitrogen gas injection device according to claim 1, further comprising a heater installed in a middle of the nitrogen supply line to heat the nitrogen gas supplied to the injection nozzle.

6. The nitrogen gas injection device according to claim 1, further comprising an orifice pipe installed in a middle of the nitrogen supply line to control the supply amount of nitrogen gas.
